(19) United States
(12) Patent Application Publication
(10) Pub. No.: US 2018/0252535 A1
(43) Pub. Date: Sep. 6, 2018

(54) Techniques for Dynamic Mapping of a Facility Using Patient Transport Apparatuses

(71) Applicant: Stryker Corporation, Kalamazoo, MI (US)

(72) Inventors: Krishna S. Bhimavarapu, Kalamazoo, MI (US); Darren G. Schaaf, Portage, MI (US)

(73) Assignee: Stryker Corporation, Kalamazoo, MI (US)

(21) Appl. No.: 15/910,507

(22) Filed: Mar. 2, 2018

Related U.S. Application Data
(60) Provisional application No. 62/466,567, filed on Mar. 3, 2017.

(51) Int. Cl. G01C 21/20; A61G 1/02; G01P 15/00; G01C 19/00; G01R 33/02; G01P 3/46; G01S 19/13; G01C 5/00

(52) U.S. Cl. CPC G01C 21/206; A61G 1/0281; G01P 15/00; G01C 19/00; A61G 2203/20; G01P 3/465; G01S 19/13; G01C 5/00; A61G 2203/36; G01R 33/02

(57) ABSTRACT

Techniques for generating a virtual map of a facility are disclosed. A server is coupled over a network to sensors equipped on patient transport apparatuses being located in the facility. The sensors produce readings as the patient transport apparatuses move in the facility. The server is configured to receive the readings over the network and to generate the virtual map of the facility based on analysis of the readings.

### RELATED APPLICATION

This application claims priority to and the benefit of U.S. Provisional Patent Application No. 62/466,567, filed on Mar. 3, 2017, the entire contents and disclosure of which are hereby incorporated herein by reference.

### BACKGROUND

Real-time locating systems (RTLS) have become an important component of tracking the indoor location of assets in the healthcare industry. The ability to accurately track the location of assets indoors has many applications in healthcare. One of the problems of RTLS is creating a detailed map of a building or facility in which the assets are tracked. To locate the assets precisely, the location of each asset is pin-pointed precisely on the map and the position of the asset is reported relative to the map. Creating such maps is not trivial. Given the number of assets that may be tracked, the number of facilities that may exist, and the complex features of such facilities, IT admins and companies may spend significant amounts of resources to generate and maintain (e.g., update) the maps and to layer the maps to locate assets. The maps typically are generated manually by having crews survey the facilities. As such, there remains an opportunity to address at least the aforementioned problems.

### BRIEF DESCRIPTION OF THE DRAWINGS

FIG. 1 is a layout of one embodiment of a mapping system for generating a virtual map of a facility based on sensor readings produced by patient transport apparatuses that move through the facility.

FIG. 2 is a perspective view of one embodiment of the patient transport apparatus.

FIG. 3 is a diagram illustrating an example of a local coordinate system of the patient transport apparatus defined with respect to a global coordinate system.

FIG. 4A is a diagram illustrating an example of logged two-dimensional paths of several patient transport apparatuses that are analyzed by the mapping system.

FIG. 4B is a diagram illustrating an example of a refined path derived from combining the logged paths from FIG. 4A, as generated by the mapping system.

FIG. 4C is a diagram illustrating an example of a hallway feature for the virtual map derived from the refined path of FIG. 4B, as generated by the mapping system.

FIG. 5A is a diagram illustrating an example of logged two-dimensional paths of two patient transport apparatuses that further recognize each other to record their locations relative to each other, as analyzed by the mapping system.

FIG. 5B is a diagram illustrating an example of a refined path derived from combining the logged paths and locations from FIG. 5A, as generated by the mapping system.

FIG. 5C is a diagram illustrating an example of a corner feature for the virtual map derived from the refined path and locations of FIG. 5B, as generated by the mapping system.

FIG. 6A is a diagram illustrating an example of logged three-dimensional paths of two patient transport apparatuses and that further recognize each other to record their locations relative to each other, as analyzed by the mapping system.

FIG. 6B is a diagram illustrating an example of a refined path derived from combining the logged paths and locations from FIG. 6A, as generated by the mapping system.

FIG. 6C is a diagram illustrating an example of an elevator and floor features for the virtual map derived from the refined path and locations of FIG. 6B, as generated by the mapping system.

FIGS. 7A-7C each illustrate a scatter plot of logged states of patient transport apparatuses in a specified location of the facility, as analyzed by the mapping system, wherein an amount of plots logged increase over time.

FIG. 7D is a diagram illustrating an example of features for the virtual map predicted from the scatter plot of logged states of FIG. 7C, as generated by the mapping system.

FIG. 8 is a diagram illustrating an example of features for the virtual map predicted from confirmed paths of two patient transport apparatuses, as generated by the mapping system.

FIG. 9 is a diagram illustrating an example of the virtual map having incorporated therewith a layer for representing signal strengths of access points disposed throughout the facility.

FIG. 10 is a diagram illustrating an example of the virtual map having incorporated therewith a layer for representing a state of a mobile computing device location within the facility.

FIG. 11 is a diagram illustrating an example of the virtual map having incorporated therewith a layer for providing captured real-world images of the facility from selected locations.

FIG. 12 is a diagram illustrating an example of the virtual map having incorporated therewith a layer for representing traffic within the facility.

### DETAILED DESCRIPTION

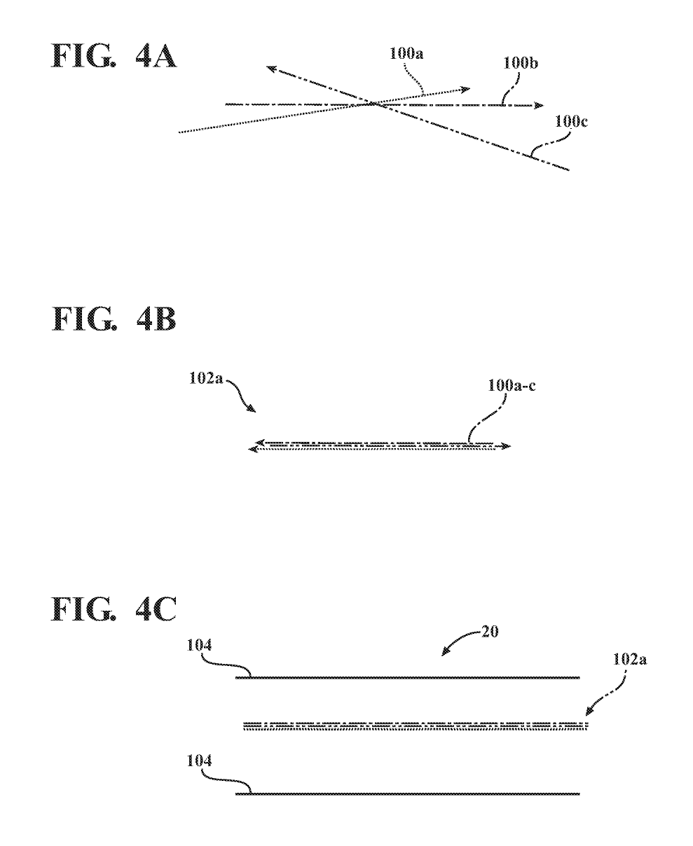

Described herein are techniques for dynamically generating a virtual map 20 (see e.g., FIGS. 4-12) of a facility 22. The techniques are implemented using a mapping system 24, components thereof, and computer-implemented methods described in detail below.

I. Mapping System Overview

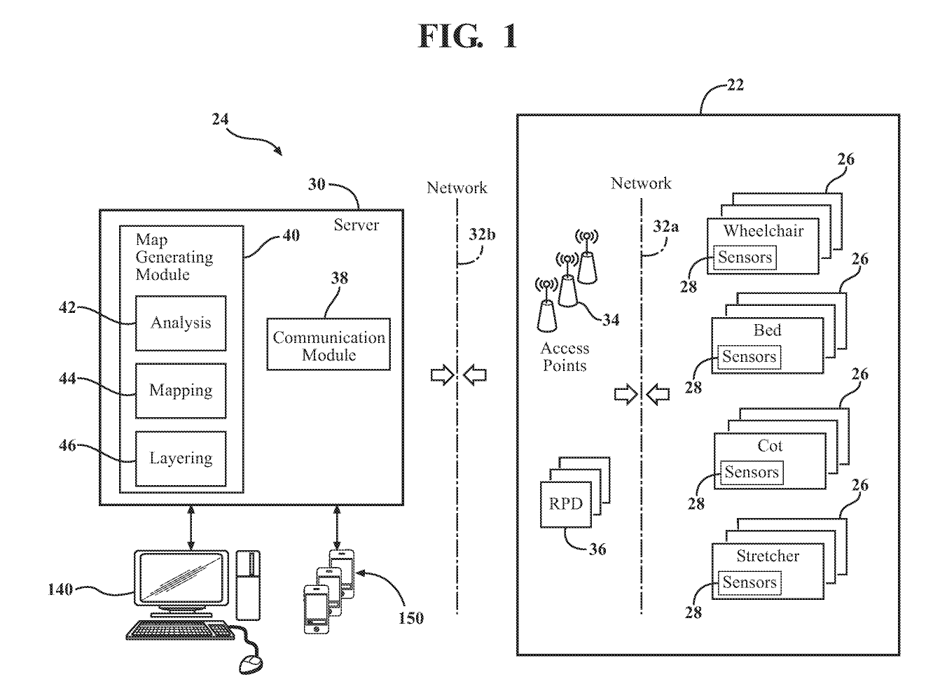

FIG. 1 illustrates a block diagram of one embodiment of the mapping system 24. The mapping system 24 comprises a plurality of patient transport apparatuses 26, which are configured to be located in the facility 22. The patient transport apparatuses 26 are equipped with sensors 28 configured to produce readings as the patient transport apparatuses 26 move in the facility 22. A server 30 is configured to receive the readings from the sensors 28 over one or more networks 32a, 32b. The server 30 is configured to analyze the readings to generate the virtual map 20 of the facility 22 based on analysis of the readings.

Access points 34 are configured to be disposed throughout the facility 22 and are configured to receive the readings from the patient transport apparatuses 26, e.g., over the network 32a, and to send the readings to the server 30, e.g., over the network 32b.

Reference point designators (RPDs) 36 are configured to be disposed at fixed locations in the facility 22 and are configured to recognize patient transport apparatuses 26 that are near to the fixed locations or that couple to the RPDs 36. The RPDs 36 are configured to receive the readings from the patient transport apparatuses 26, e.g., over the network 32a, and to send the readings to the server 30, e.g., over the network 32b.

The server 30 comprises modules implemented by hardware and/or software for executing functionality of the server 30. For example, the server 30 may comprise a communication module 38 being configured to receive the readings from the patient transport apparatuses 26, sensors 28, access points 34 or RPDs 36 over the network 32b. The communication module 38 may also be configured to send data over the networks 32a, 32b back to the patient transport apparatuses 26. The server 30 may also include a map generating module 40 being configured to generate the virtual map 20. The map generating module 40 may include sub-modules, such as an analysis sub-module 42 configured to analyze the readings from the sensors 28 of the patient transport apparatuses 26, a mapping sub-module 44 configured to implement algorithms for hypothesizing existence of landmarks of the facility 22 based on the readings received by the server 30, and a layering sub-module 46 configured to generate layers to be overlaid on the virtual map 20.

II. Embodiments of Mapping System Components

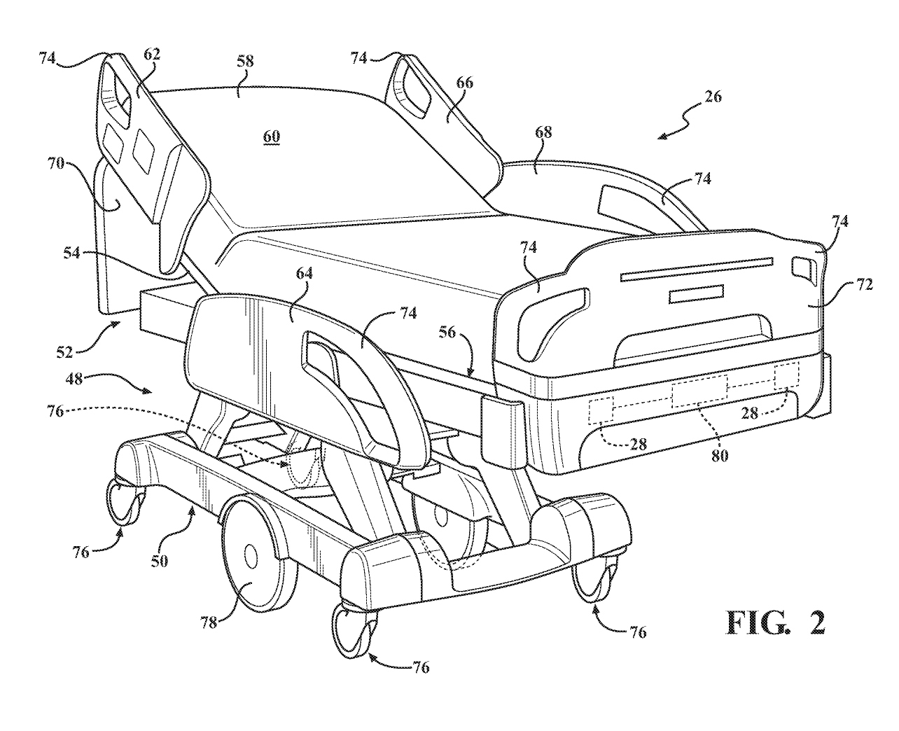

FIG. 2 illustrates one example of the patient transport apparatus 26. The patient transport apparatus 26 is for moving a patient from one location to another throughout the facility 22. The patient transport apparatus 26 illustrated in FIG. 2 is a hospital bed. In other embodiments, however, the patient transport apparatus 26 may be a stretcher, cot, wheelchair, chair, or similar apparatus. The patient transport apparatus 26 is manually moved by a user, such as a healthcare provider, etc. In some instances, the patient transport apparatus 26 may be equipped with systems for providing drive, steering, or braking assistance to the user. The patient transport apparatus 26 is moved from one location to another primarily for healthcare related purposes, i.e., moving the patient to different rooms of the facility 22, maintenance, etc.

A support structure 48 provides support for the patient during movement of the patient transport apparatus 26. The support structure 48 comprises a base 50 and an intermediate frame 52. The intermediate frame 52 is spaced above the base 50. The support structure 48 also comprises a patient support deck 54 disposed on the intermediate frame 52. The patient support deck 54 may comprise several sections, some of which are pivotable relative to the intermediate frame 52, such as a head section, a seat section, a thigh section, and a foot section. The patient support deck 54 provides a patient support surface 56 upon which the patient is supported. The patient support surface 56 is supported by the base 50.

A mattress 58 is disposed on the patient support deck 54. The mattress 58 comprises a direct patient support surface 60 upon which the patient is supported. The base 50, intermediate frame 52, patient support deck 54, and patient support surfaces 56, 60 each have a head end and a foot end corresponding to the designated placement of the patient's head and feet on the patient transport apparatus 26. The construction of the support structure 48 may take on any known or conventional design, and is not limited to that specifically set forth above.

Side rails 62, 64, 66, 68 are coupled to the intermediate frame 52. A first side rail 62 is positioned at a right head end of the intermediate frame 52. A second side rail 64 is positioned at a right foot end of the intermediate frame 52. A third side rail 66 is positioned at a left head end of the intermediate frame 52. A fourth side rail 68 is positioned at a left foot end of the intermediate frame 52. If the patient transport apparatus 26 is a stretcher or a cot, there may be fewer side rails. The side rails 62, 64, 66, 68 are movable between a raised position in which they block ingress and egress into and out of the patient transport apparatus 26, one or more intermediate positions, and a lowered position in which they are not an obstacle to enable such ingress and egress. In still other configurations, the patient transport apparatus 26 may not include any side rails.

A headboard 70 and a footboard 72 are coupled to the intermediate frame 52. In other embodiments, when the headboard 70 and footboard 72 are included, the headboard 70 and footboard 72 may be coupled to other locations on the patient transport apparatus 26, such as the base 50. In still other embodiments, the patient transport apparatus 26 does not include the headboard 70 or the footboard 72.

Operator (human control) interfaces 74, such as handles, are shown integrated into the footboard 72 and side rails 62, 64, 66, 68 to facilitate movement of the patient transport apparatus 26 over the floor surfaces throughout the facility 22. Additional operator interfaces 74 may be integrated into the headboard 70 and/or other components of the patient transport apparatus 26. The operator interfaces 74 are graspable by the operator to manipulate the patient transport apparatus 26 for movement. The operator interface 74 may comprise one or more handles coupled to the intermediate frame 52. The operator interface 74 may simply be a surface on the patient transport apparatus 26 upon which the operator locally applies force to cause movement of the patient transport apparatus 26 in one or more directions. This may comprise one or more surfaces on the intermediate frame 52 or base 50. This could also comprise one or more surfaces on or adjacent to the headboard 70, footboard 72, and/or side rails 62, 64, 66, 68. In other embodiments, the operator interface 74 may comprise separate handles for each hand of the operator. For example, the operator interface 74 may comprise two handles. Other forms of the operator interface 74 are also contemplated.

One or more wheels 76 are coupled to the base 50 to facilitate transport over floor surfaces. In one example, the wheels 76 are arranged in each of four quadrants of the base 50 adjacent to corners of the base 50. In the embodiment shown, the wheels 76 are caster wheels able to rotate and swivel relative to the support structure 48 during transport. In other embodiments, the wheels 76 are not caster wheels and may be non-steerable, steerable, non-powered, powered (driven), or combinations thereof.

Additionally, one or more auxiliary wheels 78 (powered or non-powered), which may be movable between stowed positions and deployed positions, may be coupled to the support structure 48. In some cases, when these auxiliary wheels 78 are located between the caster wheels 76 and contact the floor surface in the deployed position, they cause two of the wheels 76 to be lifted off the floor surface thereby shortening a wheel base of the patient transport apparatus 26. Such auxiliary wheels 78 may also be arranged substantially in a center of the base 50.

The wheels 76, 78 may have any suitable configuration and arrangement depending on the specific type of patient transport apparatus 26. For example, when the patient transport apparatus 26 is a wheelchair, the patient transport apparatus 26 may comprise two front caster wheels and two rear driven wheels.

As shown in FIG. 2, the patient transport apparatus 26 may be equipped with a controller 80 being configured to control functionality of the patient transport apparatuses 26, or devices powered by the patient transport apparatuses 26, e.g., the sensors 28. For example, the controller 80 may provide power to the sensors 28, analyze or modify readings received from the sensors 28, and/or enable transmission of the readings produced by the sensors 28. The controller 80 may comprise a communication device for enabling connection between the sensors 28 and the access points 34 or RPDs over the network 32a. For instance, the communication device may be RF-based, optical-based, infrared-based, or the like. The communication device may be a receiver, a transmitter, or a transceiver.

The readings may be sent to the server 30 using any type of data communication scheme or protocol. Readings may be transmitted near instantaneously (real-time), or periodically and in bulk. For example, readings may be time stamped and uploaded to the server 30 with the time stamped data. The readings of the sensors 28 may be modified, converted, transformed, grouped, or otherwise manipulated before being sent to the server 30 such that the server 30 does not technically receive readings themselves, but rather data representations of the readings. The readings may also be received by the server 30 as meta-data. It is to be appreciated that as technology continues to advance, the server 30 may be situated on the patient transport apparatus 26 itself, or other medical devices, rather than at a location remote. In such cases, the server 30 may locally receive the readings from the patient transport apparatus 26, or other medical device, on which the server 30 is situated.

In some embodiments, the controller 80 and the sensors 28 are integrated into a single unit, such that they are not separate components. The single unit may be a low cost, compact, battery operated device that can be modularly attached to any patient transport apparatus 26. In some embodiments, the single unit may be powered using energy harvesting techniques to allow simple retrofitting of the single unit on existing patient transport apparatuses 26. Examples of the energy harvesting techniques for patient transport apparatuses 26 are described in U.S. Provisional Patent Application No. 62/576,303 filed on Oct. 24, 2017 entitled “ENERGY HARVESTING AND PROPULSION ASSISTANCE TECHNIQUES FOR A PATIENT TRANSPORT APPARATUS,” the entire contents of which are hereby incorporated by reference.

The controller 80 may comprise any suitable signal processing means and computer executable instructions or software modules stored in non-transitory memory wherein the executable instructions or modules may be executed by a processor, or the like. Additionally, or alternatively, the controller 80 may comprise a microcontroller, one or more integrated circuits, logic parts, and the like for enabling the same. The controller 80 may have any suitable configuration for enabling the controller 80 to perform various tasks related to operation of the patient transport apparatus 26, such as those described below. The sensors 28 may be of various types and configurations and may be configured to provide distinct information about movement of the patient transport apparatus 26 throughout the facility 22.

The sensor 28 may be a speed or velocity sensor configured to produce readings indicative of a velocity of the patient transport apparatus 26 as the patient transport apparatus 26 moves through the facility 22. In one example, the velocity sensor is a tachometer or wheel speed sensor for reading a rotational speed of any of the wheels 76, 78. The velocity sensor may be a rotary, optical, magnetic, piezo speed sensor, and the like. The velocity sensor may be coupled to any suitable component of the patient transport apparatus 26.

In other examples, the sensor 28 may be a tachometer configured to produce readings indicative of rotational speeds of the wheels 70, 72 of the patient transport apparatus 26. From this rotational speed, the velocity of the patient transport apparatus 26 through the facility 22 can be determined. The tachometer may be electrical, mechanical or electromechanical, contact or non-contact type, and analog or digital. Other types of tachometers besides those described herein are contemplated.

In other examples, the sensor 28 is an encoder configured to detect rotational position of the wheels 70, 72 of the patient transport apparatus 26. From encoder measurements, readings are produced that are indicative of position or location of the patient transport apparatus 26 in the facility 22. Alternatively, encoder measurements may be utilized to calculate a traversed distance of the patient transport apparatus 26 from a given starting point. Any suitable type of encoder may be utilized, such as absolute rotary encoders (e.g., mechanical, optical, magnetic, capacitive, etc.), or the like.

The sensor 28 may be an accelerometer configured to measure the acceleration forces acting on the patient transport apparatus 26. The accelerometer is configured to produce readings indicative of accelerations of the patient transport apparatus 26 as it moves through the facility 22. Such acceleration forces may be static (e.g., gravitational acceleration acting on the patient transport apparatus 26) or dynamic (e.g., acceleration from movement, turning, shock, or vibration applied to the patient transport apparatus 26). Additionally, readings from the accelerometer may be used to derive velocities or positions of the patient transport apparatus 26. The accelerometer may also be utilized to measure acceleration forces acting on components of the patient transport apparatus 26, such as the operator interfaces 74, or the like. In one example, the accelerometer is utilized as an (single or multi-axis) inclinometer or a tilt sensor to measure a slope of the floor surface upon which the patient transport apparatus 26 rests, with respect to gravity. In some instances, the accelerometer may be utilized for power on/sleep mode detection and conserving power for the patient transport apparatus 26. Examples of the accelerometer may be any type such as, but not limited to, piezoelectric, charge mode piezoelectric, variable capacitance, microelectromechanical systems (MEMS), strain gauge-based, resonance based, and the like.

In another example, the sensor 28 is a gyroscope configured to produce readings indicative of direction of the patient transport apparatus 26 within the facility 22. For example, the gyroscope may measure rotational motion or angular velocity. The measured rotation or angular velocity may be used to derive rotational direction of the patient transport apparatus 26. In one embodiment, the gyroscope is a microelectromechanical system (MEMS) or Coriolis vibratory gyroscope configured to utilize vibration to detect rotation rates. In some instances, the gyroscope may be combined with the accelerometer to achieve output that has six degrees of freedom (DOF). The gyroscope may also be understood as an angular rate sensor. Examples of gyroscopes other than those described herein may be utilized.

The sensor 28 may also be a magnetometer configured to produce readings indicative of direction of the patient transport apparatus 26 in the facility 22. The magnetometer comprises elements sensitive to magnetic field changes. This sensitivity can be compared with the magnetic field of other objects or the earth to determine directional components that vary as direction of the patient transport apparatus 26 changes. The magnetometer may be a three-axis device such that changes in orientation or elevation to not affect readings of the magnetometer. Examples of the magnetometer include, but are not limited to Hall effect sensors, vector magnetometers, scalar magnetometers, and the like.

In another example, the sensor 28 is an altimeter configured to produce readings indicative of altitudes of the patient transport apparatus 26 in the facility 22. The altimeter may measure such altitudes with respect to a fixed reference height, e.g., earth ground. In one example, the altimeter is a pressure altimeter configured to measure altitude based on changes in atmospheric or barometric pressure. In another example, the altimeter may additionally measure ambient temperature to supplement altitude measurements. The altimeter may be a module, a MEMS system, and the like. The altimeter may comprise any suitable components, such as A/D converters, high sampling devices, etc., for providing accurate measurements.

The sensor 28 may also be an infrared sensor configured to produce readings for communication with other patient transport apparatuses 26 or the RPDs 36 in the facility 22. For example, the infrared sensor may be utilized to receive infrared readings from other patient transport apparatuses 26 within proximity of the infrared sensor to enable recognition of such other patient transport apparatuses 26. The infrared sensor may be active or passive and may be any type of infrared sensor, such as optical, thermal, quantum, etc.

In yet another example, the sensor 28 may be a GPS sensor configured to produce readings indicative of positions of the patient transport apparatus 26 in the facility 22. In one example, the GPS sensor comprises a receiver and an antenna that receive satellite-based readings to provide position (e.g., latitude, longitude, altitude), velocity, and timing information about the patient transport apparatus 26. The GPS sensor may be provided to detect position, velocity, and timing of the patient transport apparatus 26 in addition to, or independent of using the RPDs 36. The GPS sensors may be any suitable type, including differential (DPGS), and the like. In some embodiments, the GPS sensors are optional and are used in conjunction with other sensor types described herein due to accuracy limitations of some GPS sensors in tracking objects indoors.

Any of the aforementioned sensors 28 may be utilized individually, or in combination with one or more of the other sensors 28. The patient transport apparatus may be equipped with any other type of sensors 28 including, but not limited to proximity sensors (e.g., ultrasonic, capacitive, photoelectric, inductive, magnetic, etc.), image sensors (e.g., cameras, camera modules, CCD-based, CMOS-based, etc.), motion detectors (infrared, ultrasound, microwave, radar etc.), and the like. Additionally, multiple sensors 28 may be integrated into a single unit comprising a common housing or PCB on/in which the sensors 28 are disposed.

The sensors 28 may also be configured to provide distinct information about the direction of movement and/or orientation in which the patient transport apparatus 26 moves, e.g., with the head end leading or with the foot end leading. For example, the sensors 28 may be placed with respect to head end and foot end of the patient transport apparatuses 26 so that more specific information regarding orientation of the patient transport apparatuses 26 can be obtained. Even when stationary, the sensors 28 are able to provide information regarding the location of the patient transport apparatus 26 based on such predefined placement of the sensors 28 on the patient transport apparatuses 26. The sensors 28 may be located at any suitable location on the patient transport apparatuses 26, with such location stored in memory and retrievable by the server 30.

In addition to the patient transport apparatuses 26, other supplemental devices or systems that are configured to move through the facility 22 may be equipped with any of the aforementioned sensors 28. Such supplemental devices or systems may provide data complementary to the data from the patient transport apparatuses 26 to facilitate generation of the virtual map 20. In one embodiment, the supplemental devices or systems are related to healthcare, and include, for example, medical laundry carts, medical waste transportation carts, and moveable medical systems (e.g., robotic carts, imaging carts, computer carts, IV towers, anesthesia carts, tool cabinets, and the like.)

The server 30 may have any suitable configuration for receiving and analyzing the readings from the sensors 28 to generate the virtual map 20. The server 30 may be any type of server depending on the functionality or purpose of the server 30. Such server types include, but are not limited to file servers, domain servers, database servers, application servers, and the like. The server 30 may be one, or a plurality of servers. The server 30 may comprise non-transitory memory, e.g., read only memory (ROM) or random access memory (RAM), for storing data and/or computer-executable instructions, such as software, modules, algorithms, etc. These instructions, when executed by one or more processors at the server 30, are configured to implement some of the server 30 techniques described herein. The server 30 may include other programmable systems or components, such as microcontrollers, reduced instruction set circuits (RISC), application specific integrated circuits (ASIC), programmable logic circuits (PLC), and any other circuit or processor capable of executing the functions described herein. The server 30 may be physically located at the facility 22. Alternatively, the server 30 may be physically located at a site that is remote from the facility 22.

The facility 22, as used herein, is intended to describe any location where a plurality of patient transport apparatuses 26 are disposed and for which generation of the virtual map 20 is desired. Examples of the facility 22 include, but are not limited to, a healthcare facility, treatment center, hospital, rehabilitation center, storage facility, warehouse, office building, etc. Examples of other facilities 22 besides those described herein are contemplated.

When generated, the virtual map 20 of the facility 22 is configured to digitally represent features of the facility 22 on a display device. Such features include, but are not limited to, walls, corners, rooms, stairways, ramps, elevators, closets, fixtures (e.g., medical equipment, shelving units, tables, stations, etc.), and the like. The virtual map 20 may be two-dimensional or three-dimensional. The virtual map 20, for example, may be represented metrically in two-dimensional space in which objects are placed with precise coordinates. When two-dimensional, the virtual map 20 may represent, e.g., a plan view of a level (floor) of the facility 22. When three-dimensional, the virtual map 20 may represent a perspective view of the facility 22, including a single level or multiple levels of the facility 22. In such instances, the virtual map 20 may be represented topologically, such that the virtual map 20 is a graph that takes into account places and relations between them using nodes corresponding to places and arcs corresponding to the paths. The virtual map 20 may be rendered using any suitable software, such as computer-aided design (CAD), 3D wireframe, 3D solid modeling, Non-uniform rational Basis spline (NURBS) modeling, etc.

The access points 34 may be any suitable type for enabling wireless communication with the patient transport apparatuses 26. The access points 34 may communicate wirelessly using any suitable technology protocol, such as Bluetooth (IEEE 802.15.1), Wi-Fi (IEEE 802.11), ZigBee (IEEE 802.15.4), and the like. In one embodiment, the access points 34 are wired to the network 32b and the access points 34 enable the patient transport apparatuses 26 to connect to the network 32b. In some embodiments, one or more access points 32 may be hot-spots providing direct Wi-Fi access to the network 32b. For added security, the controller 80 of each patient transport apparatus is provided with a passcode (e.g., WPA, WPA2, etc.) for connecting to the access points 34. The access points 34 may be disposed throughout the facility 22 according to any configuration to enable sufficient signal strength to reach parts of the facility 22 for which generation of the virtual map 20 is desired. The access points 34 may have configurations other than those described herein.

The RPDs 36 are optionally provided at fixed locations throughout the facility 22 to recognize patient transport apparatuses 26 within proximity of the fixed location and to provide fixed references for facilitating generation of the virtual map 20. Unlike the access points 34, whose locations may not be determinable with specificity, the RPDs 36 are designated at specifically determinable locations relative to the facility 22.

The RPDs 36 may have any suitable configuration. In one embodiment, the RPDs 36 comprise docking stations (i.e., headwalls) installed at various locations in the facility 22, such as in patient rooms, x-ray rooms, intensive care, emergency rooms, or the like. The docking stations may releasably engage the patient transport apparatuses 26 to provide additional functionality or services for patient care. The docking stations may be compatible with most or all of the patient transport apparatuses 26 so that any of the patient transport apparatuses 26 can be engaged by any of the docking stations. The docking stations may be configured to be floor-mounted or ceiling-mounted. The docking stations may also move the components of the patient transport apparatuses 26 in multiple degrees of freedom, such as lifting/lowering, tilting, rotating, etc.

The docking station may comprise a controller configured to establish communication with the patient transport apparatus 26. Such communication may be automatically established using data communication links. The docking station may comprise a communication device (e.g., receiver) for communicating with the controller 80 of the patient transport apparatus 26. The patient transport apparatus 26 may communicate with the docking station using wireless or wired means of communication. In one example, the docking station and the patient transport apparatus 26 each comprise a unique identifier (ID). When communication is established between the docking station and the patient transport apparatus 26, both IDs are linked. Examples of the docking stations and communication techniques between the docking stations and the patient transport apparatuses 26 are described in U.S. Patent Application Publication No. 2016/0038361, entitled “Patient Support Apparatuses with Wireless Headwall Communication,” filed on Aug. 6, 2015, the entire contents of which are hereby incorporated by reference.

In other embodiments, the RPD 36 may be other devices, such as beacons (e.g., Bluetooth) or IR wall modules/units, strategically placed at fixed locations throughout the facility 22. In one embodiment, the RPDs 36 recognize patient transport apparatuses 26 within a distance between 0-10 ft. The RPDs 36 may communicate with the patient transport apparatuses 26 using any suitable form of communication, e.g., Bluetooth, Wi-Fi, ZigBee, Infrared, etc. Depending on the communication configuration, the RPDs 36 may or may not use the network 32a to communicate with the patient transport apparatus 26. To communicate with the server 30, the RPDs 36 may communicate directly to the server 30 over the network 32b and/or through one or more access points 34.

Networks 32a, 32b may have various configurations. The networks 32a, 32b may be two separate networks as shown in FIG. 1. For example, the network 32a may be reserved for communication within the facility 22 between any combination of the patient transport apparatuses 26, the access points 34, and/or the RPDs 36. Alternatively, the networks 32a, 32b may be one common network or may comprise separate networks. Examples of the networks 32a, 32b, include, but are not limited to local area networks (LAN), wide area networks (WAN), enterprise private networks (EPN), storage area networks (SAN), personal area networks (PAN), or any type of wireless network (e.g., Wi-Fi, Internet, etc.), or the like. Additionally, the networks 32a, 32b may have any suitable topology depending on the configuration of devices connected thereto. Such topologies include, but are not limited to mesh, star, bus, ring and tree topologies. The networks 32a, 32b may have configurations other than those described herein.

The mapping system 24, and any of the components thereof, may have configurations other than those described herein for enabling acquisition and transmission of data related to the patient transport apparatuses 26 to facilitate generation of the virtual map 20.

III. Techniques for Generation of the Virtual Map

With embodiments of the mapping system 24 described, techniques for generation of the virtual map 20 are described herein.

Generation of the virtual map 20 depends on movement of the patient transport apparatus 26, and more specifically, a fleet of patient transport apparatuses 26. As described, each patient transport apparatus 26 is moved from one location to another primarily for healthcare related purposes, i.e., moving the patient to different rooms of the facility 22, maintenance, etc. Unlike purely autonomous robots, which move autonomously along paths, the patient transport apparatuses 26 are primarily controlled by the user for the healthcare related purposes. In other words, the primary purpose for moving the patient transport apparatus 26 is not to generate the virtual map 20. Instead, the techniques described herein exploit already occurring movement of the patient transport apparatuses 26 to facilitate generation of the virtual map 20.

As will be demonstrated, portions of the virtual map 20 may be inconsistent and inaccurate. However, as more readings from the patient transport apparatuses 26 are acquired and stored by the server 30, the server 30 is able to more accurately and/or efficiently generate the virtual map 20 by merging and synthesizing portions into one coherent virtual map 20. As such, communication between the patient transport apparatuses 26 and the server 30, as well as communication of the patient transport apparatuses 26 with each other are utilized for generation of the virtual map 20.

The readings received by the server 30 over the network 32b generally relate to movement characteristics of the patient transport apparatuses 26. Using the analysis sub-module 42 of the mapping generation module 40, the server 30 is configured to analyze the readings to make determinations about patient transport apparatus 26, and ultimately the facility 22, for generation of the virtual map 20.

In one embodiment, the readings may be indicative of paths of movement of the patient transport apparatuses 26 throughout the facility 22. The paths of movement may be determined in various manners. For example, current locations of the patient transport apparatuses 26 may be transmitted and logged, either by the patient transport apparatuses 26 or by the server 30. Logged locations may be analyzed to make determinations about the path of movement.

Location or path determinations may further be facilitated through communication between the patient transport apparatuses 26 themselves. For example, when two patient transport apparatuses 26 cross each other, or are in close proximity to each other, the patient transport apparatuses 26 are configured to recognize each other using short-range communication and/or the sensors 28. For example, one patient transport apparatus 26 may utilize infrared emitters and sensors, respectively, to produce signals for and receive readings from infrared emitters and sensors of the other patient transport apparatus 26 to enable such recognition. Other types of communication means many be employed to enable such cross talk, such as RF communication. Each patient transport apparatus 26 is configured to then log its location on the path. As described below, the logged location may be determined relative to a local coordinate system 90 of the respective patient transport apparatus 26 or relative to a global coordinate system 92. By using this type of cross talk, each patient transport apparatus 26 is configured to confirm its path with the location or path of the other patient transport apparatus 26. Furthermore, confirmation of the paths may involve reorientation of the paths with respect to each other. The logged locations may be stored locally on the patient transport apparatuses 26 and may be transmitted to the server 30. Additionally, logging locations of the patient transport apparatuses 26 may occur when the patient transport apparatuses 26 recognize each other, as described, but also when the patient transport apparatuses 26 are near RPDs 36.

The confirmation or orientation outcomes of such cross talk may be determined (or fused) by controllers 80 of the patient transport apparatuses 26 and then communicated to the server 30. Alternatively, the server 30 may determine confirmation or orientation outcomes based on cross talk readings received from the patient transport apparatuses 26 over the networks 32a, 32b. Again, with a fleet of patient transport apparatuses 26, the frequency of cross talk occurrences increases, thereby increasing accuracy and confirmation of the paths.

In one embodiment, paths of movement may be determined by a combination of velocity readings (e.g., from the velocity sensor), direction readings (e.g., from gyroscopes or magnetometers), and time readings which may be analyzed by the server 30 to determine lengths of hallways for the virtual map 20. For instance, trajectory of logged locations may indicate direction of the path, starting and ending points of logged locations may indicate starting and ending points of the path, and spacing between logged locations may be used to calculate velocity of the patient transport apparatus 26 along the path, etc. Starting and ending points may be determined by analyzing motion of the patient transport apparatus 26 with respect to time. Mainly, when the patient transport apparatus 26 is not moving for a predetermined period of time and then begins to move, a starting point may be registered. Similarly, when the patient transport apparatus 26 is moving but then stops moving for a predetermined period of time, an ending point may be registered. Alternatively, starting and ending points of the path may be determined based on constant velocity, direction, or the like, between two logged locations.

Using such paths, the server 30 is configured to generate preliminary lines and landmarks for the virtual map 20. When enough lines and landmarks (e.g., corners, hallways, rooms, etc.) for the virtual map 20 are generated, the server 30 may use techniques, such as those described below, to further refine the lines and landmarks to more accurately define the virtual map 20.

The server 30 may analyze readings to make other determinations about the facility 22 for generation of the virtual map 20. For example, the server 30 may analyze altimeter readings for determining how many floors exist in the facility 22, and which floors of the facility 22 patient transport apparatuses 26 are located on. The virtual map 20 may be generated to reflect the determined number of floors.

In another example, velocity, direction, and altimeter readings may be analyzed in combination by the server 30 to determine when and where patient transport apparatuses 26 are going up or down in the facility 22. If the patient transport apparatuses 26 are going up or down from a common location, the server 30 may identify that the common location is an elevator. The virtual map 20 may be generated to reflect the location of the elevator on applicable floors.

In other instances, velocity and direction or altimeter readings may be analyzed in combination by the server 30 to determine when and where patient transport apparatuses 26 gradually incline or decline along a path in the facility 22. If the patient transport apparatuses 26 are gradually inclining or declining from along a common path, the server 30 may identify that the common path is a ramp. The virtual map 20 may be generated to reflect the location and length of the ramp.

In yet another example, infrared readings may be analyzed in combination with other readings by the server 30 to determine when and where patient transport apparatuses 26 cross each other in the facility 22. These determinations may be iteratively performed by the server 30 to confirm, refine, reorient and/or correct prior determinations about features of the virtual map 20.

The server 30 is configured to generate features of the virtual map 20 using probabilistic methods or algorithms. For example, the server 30 is configured to hypothesize the existence of landmarks and features in the facility 22 for the virtual map 20 based on analyzing readings, paths, or refined paths from the patient transport apparatuses 26 over time. The server 30 then tests hypothesized existence of such landmarks or features using probabilistic methods or algorithms. As more paths are created, the server 30 assimilates the data to refine the accuracy of previously predicted paths and landmarks.

In one embodiment, the probabilistic methods or algorithms are employed using the mapping sub-module 44. The mapping sub-module 44 is configured to solve mapping problems related to defining the virtual map 20 based on the received readings from the patient transport apparatuses 26 to define the environment of the facility 22 in which the patient transport apparatuses 26 are present.

The mapping sub-module 44 may also be configured to solve localization problems related to estimating a pose (i.e., location and direction) of the patient transport apparatuses 26 relative to the virtual map 20. Thus, the mapping sub-module 44 is configured to implement techniques to generate the virtual map 20 while at the same time localizing the patient transport apparatuses 26 within the virtual map 20. The mapping sub-module 44 may do so even though readings from the sensors 28 may inherently be noisy or inaccurate and may do so even without prior knowledge about the virtual map 20 or the locations of the patient transport apparatuses 26.

However, considering that the patient transport apparatuses 26 are moved by users, as described, navigation and localization of the patient transport apparatuses 26 are effectively also performed by the users. As such, the patient transport apparatuses 26 are responsible for providing data related to mapping, rather than autonomously performing localization and navigation to solve localization problems. Such techniques for solving the mapping problems are not trivial.

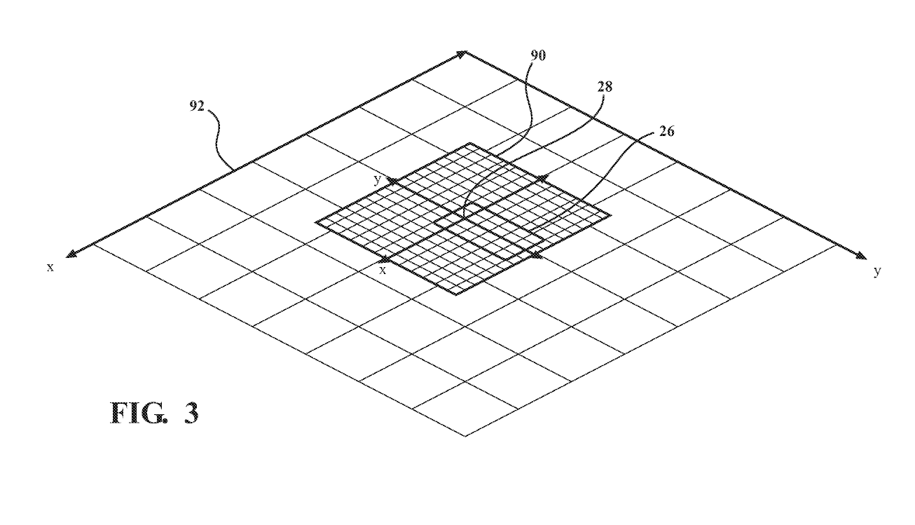

As shown in FIG. 3, each patient transport apparatus 26 may have its own local coordinate system 90. The local coordinate system 90 may be defined with respect to any part or component of the patient transport apparatus 26. For example, the sensor 28 may be used as the origin of the local coordinate system 90. The local coordinate system 90 moves and rotates in response to movement and rotation of the patient transport apparatus 26.

Additionally, the local coordinate system 90 may be located and monitored by the server 30 within a global coordinate system 92, in which the virtual map 20 may be defined. The global coordinate system 92 may initially be arbitrarily defined. In one embodiment, the state of the patient transport apparatus 26 is defined as the root of the global coordinate system 92. Alternatively, the mapping sub-module 44 may begin with some pre-existing features in the virtual map 20 to establish the root of the global coordinate system 92 (e.g., to establish a 3-D global coordinate space with fixed origin and axes), having uncertainty relative to the state of the patient transport apparatus 26. The coordinate systems 90, 92 may be two or three dimensional.

As the patient transport apparatus 26 moves throughout the facility 22, the mapping sub-module 44 calculates, predicts or otherwise generates estimates about a current state of the patient transport apparatus 26 relative to the global coordinate system 92 (e.g., a current position and/or orientation of the local coordinate system 90 in the global coordinate system 92), as well as a level of uncertainty about the current state. In one example, the current state of the patient transport apparatus 26 is predicted from the previous state estimate and the time step. Observations about features of the facility 22 (analyzed from the sensor 28 readings) are estimated from the predicted current state.

Based on continued readings received by the server 30, the mapping sub-module 44 generates new features for the virtual map 20 and/or re-measures previously generated features of the virtual map 20. In other words, differences between the predicted observation and the actual observation are computed. Thereafter, predictions about the current state are updated. The processes of estimating position and/or orientation of the patient transport apparatus 26 in the global coordinate system 92, and generating/updating features of the virtual map 20 are repeated as appropriate.

The mapping sub-module 44 may utilize any suitable probabilistic algorithm for solving the mapping and localization problems, including, but not limited to any one or combination of the following: Bayes filtering or estimation, Kalman filtering, hybrid Kalman filtering, extended Kalman filtering, particle filtering, Monte Carlo localization, expectation maximization (EM) algorithms, density estimation, probability hypothesis density (PHD) filters, Lu/Milios algorithms, maximum likelihood (ML) algorithms, occupancy grid algorithms, multi-planar mapping techniques, and the like.

FIGS. 4-6 illustrate examples of how the server 30 analyzes readings to generate certain features of the virtual map 20. For example, FIGS. 4A-4C illustrate one example of how the server 30 generates a hallway 104 of the facility 22 for the virtual map 20. In FIG. 4A, the server 30 receives readings (e.g., direction and velocity) from several different patient transport apparatuses 26. The readings are analyzed by the server 30 to determine relative direction of the path of each patient transport apparatus 26, i.e., paths 100a-100c. The paths 100a-100c, as shown in FIG. 4A, are not aligned due to differing paths of movement, inherent limitations of sensor readings (e.g., drift, noise, etc.), and/or the general lack of information available to the server 30 at early stages of virtual map 20 generation. Moreover, the paths 100a-100c may be defined in the global coordinate system 92 without any particular localization to fixed features of the facility 22. Nevertheless, the server 30 is configured to determine similarities given the general locations of the paths 100a-100c.

At FIG. 4B, the server 30 aligns the paths 100a-100c to generate a refined path 102a. The refined path 102a may be a reorientation of the paths 100a-100c or may be a consolidation/combination/merger of the paths 100a-100c to generate one refined path 102a. The refined path 102a may or may not take into account a direction of movement of each path 100a-100c. The refined path 102a may be updated continuously based on future determined paths 100n until a predetermined threshold is reached. The predetermined threshold may represent, for example, that the refined path 102a has reached an acceptable level of accuracy such that further refinement would yield negligible or no meaningful update. The refined path 102a in FIG. 4B may be confirmed using the aforementioned cross talk methods as well. In so doing, the generation of the refined path 102a may be improved or accelerated because the relative locations of the paths 100a-100c are confirmed relative to the others. In some instances, the process of generating the refined path 102a may be implemented using logged locations of the patient transport apparatuses 26 if the paths 100a-100c are unavailable, by using the techniques described herein. For instance, the refined path 102a may be generated by interpolating discrete points of logged locations of patient transport apparatuses 26 or by correlating discrete points of one patient transport apparatus 26 with the path 100 of another patient transport apparatus 26.

At FIG. 4C, the server 30 renders a hallway 104 feature of the virtual map 20 based on the refined path 102a. For example, the hallway 104 may be aligned in parallel to the refined path 102a. A width of the hallway 104 may be generated based on a range of movement of the paths 100a-100c in the general location of the virtual map 20. Any of the above-described probabilistic techniques may be utilized for predicting features, such as the width of the hallway, etc. Once the hallway 104 is generated, the server 30 may import the hallway 104 into the virtual map 20. Hallways throughout the facility 22 may be generated in a similar manner as described given that the patient transport apparatuses 26 move through such hallways. Moreover, this process may be performed to generate features other than hallways of the facility 22.

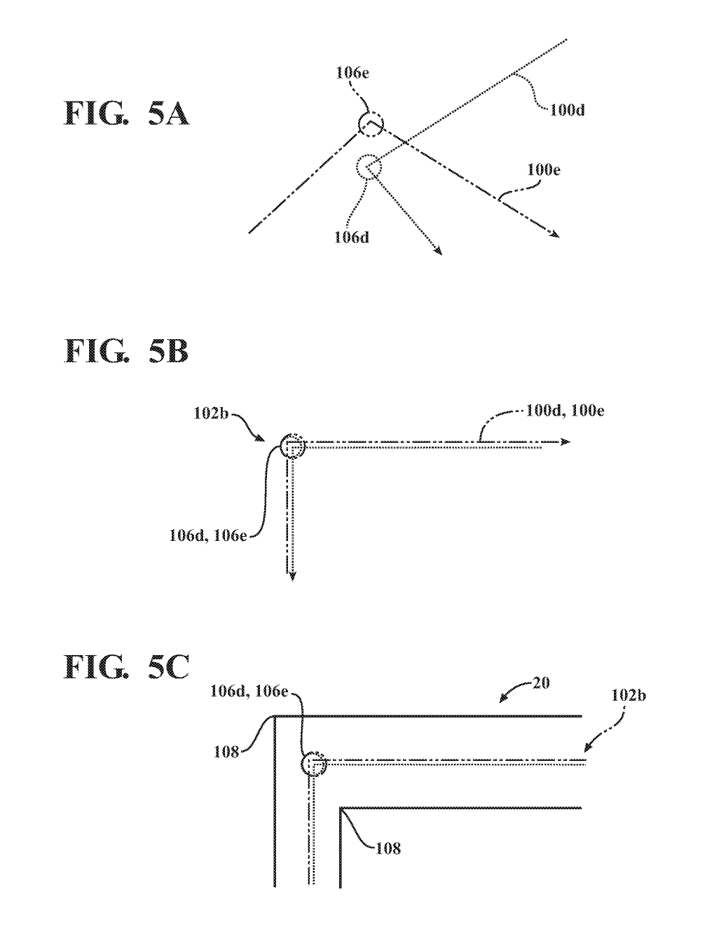

FIGS. 5A-5C illustrate an example of how the server 30 generates a corner 108 of the facility 22 for the virtual map 20. In FIG. 5A, the server 30 receives readings (e.g., infrared, direction, and velocity) from two different patient transport apparatuses 26 to determine two paths 100d, 100e. In this example, the patient transport apparatuses 26 cross talk when they cross each other such that their relative locations are logged relative to the other. Here, the locations at the time of cross talk are identified by 106d, 106e (e.g., the locations refer to a location of the respective origins of the local coordinate systems 90 of the patient transport apparatuses 26, which may originate at one of the sensors 28). In this example, the patient transport apparatuses 26 communicate with each other near the corner 108. Again, the paths 100d, 100e, as shown in FIG. 5A, are not initially aligned for one or more of the reasons stated above.

At FIG. 5B, the paths 100d, 100e and relative cross talk locations 106d, 106e are analyzed by the server 30. Here, the server 30 can directly reorient or align the paths 100d, 100e by aligning the locations 106d, 106e (e.g., by aligning the respective local coordinate systems 90 of the associated patient transport apparatuses 26). That is, presence of locations 106d, 106e enables more rapid reorienting or aligning of the paths 100d, 100e compared with situations when locations 106d, 106e are not present. The aligned paths 100d, 100e are used to generate the refined path 102b.

At FIG. 5C, the server 30 renders the corner 108 feature of the virtual map 20 based on the refined path 102b. For example, because locations 106d, 106e were logged on each respective path 100d, 100e near the corner 108 of the facility 22, a corner of refined path 102b is aligned at a center of the corner 108. As described, dimensions of the corner 108 may be generated based on a range of movement of the paths 100d, 100e or any of the probabilistic techniques described herein. Once the corner 108 is generated, the server 30 may import the corner 108 into the virtual map 20. As more and more features of the facility 22 are generated in the virtual map 20, the server 30 may connect such features to progressively draw the virtual map 20. For example, the corner 108 of FIG. 5C may be connected to the hallway 104 of FIG. 4C, or the like. Corners throughout the facility 22 may be generated in a similar manner as described given that the patient transport apparatuses 26 move through such corners. Moreover, this process may be performed to generate features other than corners of the facility 22.

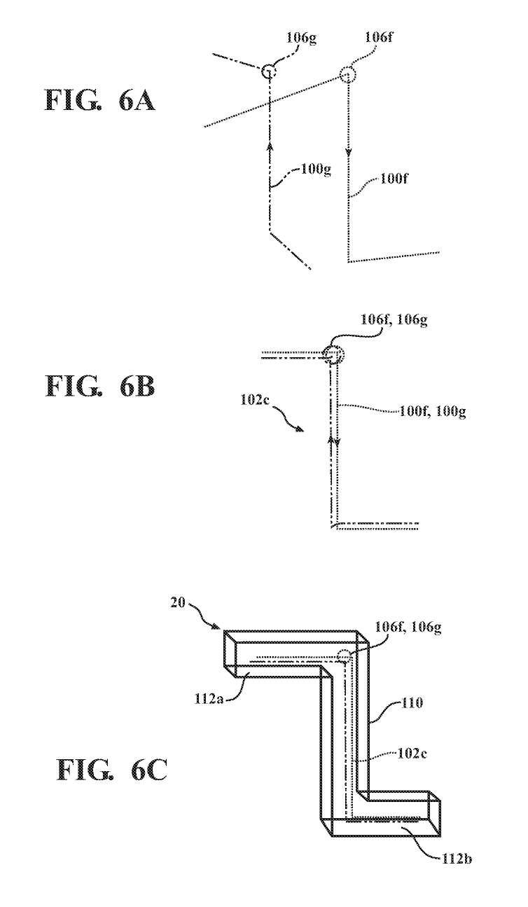

In yet another example, FIGS. 6A-6C illustrate how the server 30 generates an elevator 110 location and identifies upper and lower floors 112a, 112b of the facility 22 for the virtual map 20. In FIG. 6A, the server 30 receives readings (e.g., infrared, direction, velocity, and altimeter) from two different patient transport apparatuses 26 to determine two paths 100f, 100g. In this example, the paths 100f, 100g are illustrated in a three-dimensional manner. The patient transport apparatuses 26 are moving between the floors 112a, 112b of the facility 22 through the elevator 110 in opposite directions. The patient transport apparatuses 26 cross talk when they pass each other near the elevator 110 exit on the upper floor 112a such that each of their locations in the global coordinate system 92 are logged relative to the other. Here, the locations at the time of cross talk are identified by 106f, 106g.

At FIG. 6B, the paths 100f, 100g and relative cross talk locations 106f, 106g are analyzed by the server 30. Here, the server 30 generates refined path 102c by aligning the locations 106f, 106 and reorienting the paths 100f, 100g. In this example, the paths 100f, 100g are aligned in three-dimensions, i.e., through the elevator 110 shaft and through portions of the upper and lower floors 112a, 112b adjacent the exit/entrance of the elevator 110. At FIG. 6C, the server 30 renders the elevator 110 and floors 112a, 112b for the virtual map 20 based on the refined path 102c. Similar techniques can be employed for other features of the virtual map 20 having different altitudes, i.e., ramps, stairs, etc. Additionally, although the hallway 104, corner 108, elevator 110, and floors 112a, 112b are explained as features that can be generated for the virtual map 20 based on the above-described techniques, it is to be appreciated that any other features of the facility 22 may be generated in a similar manner for the virtual map 20.

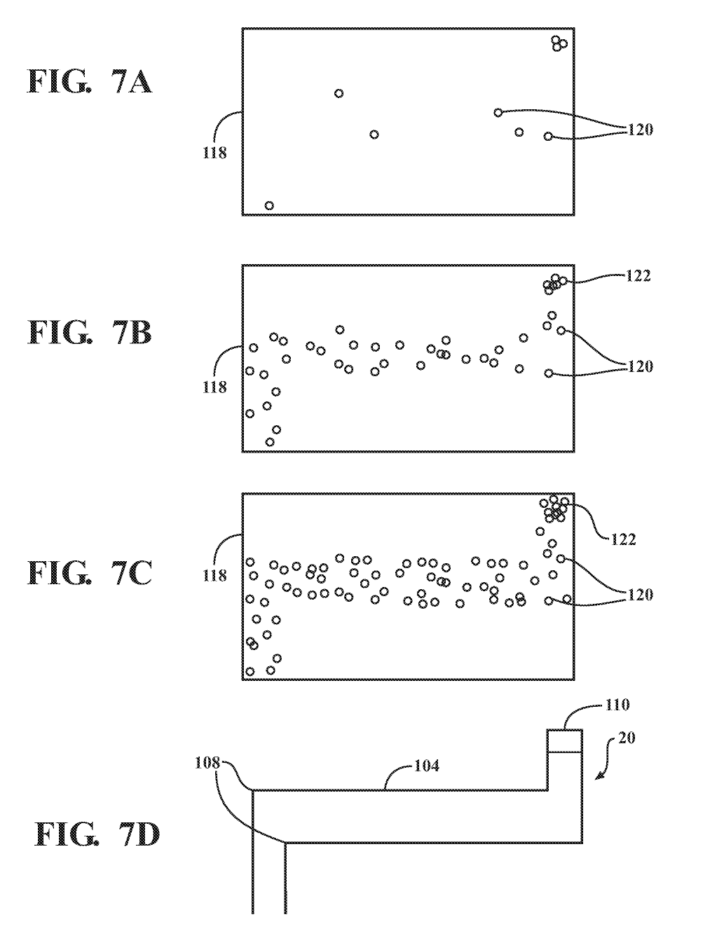

In FIGS. 7A-7D, a different approach is used by the server 30 to generate features of the virtual map 20. In this example, the server 30 collects readings from the sensors 28 of several patient transport apparatuses 26 over time for a specific region 118 of the facility 22. Said differently, the server 30 generates a density reading of activity in the specific region 118 of the facility 22 over time, rather than at only one point in time. The readings in this example relate to the state of each of the patient transport apparatuses 26 in the global coordinate system 92, and more specifically the specific region 118 in the global coordinate system 92, at various sampling times. The readings may be any of the aforementioned readings of the sensors 28 described above (e.g., location, velocity, altitude, etc.). The readings are plotted by the server 30 in FIG. 7A rendering a scatter of plots 120 that are well separated thereby forming no feature of the facility 22 that is resolvable by the server 30 for generation of the virtual map 20. In FIG. 7B, after the server 30 has collected more readings over time, the plots 120 begin to cluster at some locations, i.e., at 122, and features of the facility 22 are somewhat resolvable by the server 30 with a low-level of accuracy.

As more and more readings are plotted, the server 30 at FIG. 7C, is able to resolve features of the facility 22 with a high-level of accuracy. Specifically, using predictive techniques described herein, the server 30 is configured to estimate that the plots 120 form a hallway 104, a corner 108 and an elevator 110 location for the virtual map 20, as shown in FIG. 7D. For example, the hallway 104 and corner 108 may be predicted based on the density or distribution of the plots 120, which are spatially limited to the hallway 104 or corner 108 widths, as shown. The elevator 110 location may be predicted by the server 30 using location and altimeter readings, wherein the plots 120 are based on variable altimeter readings at the cluster 122. In other words, if the patient transport apparatuses are changing altitude only at this cluster 122, the server 30 can use predictive techniques to determine that the elevator 110 must be located here.

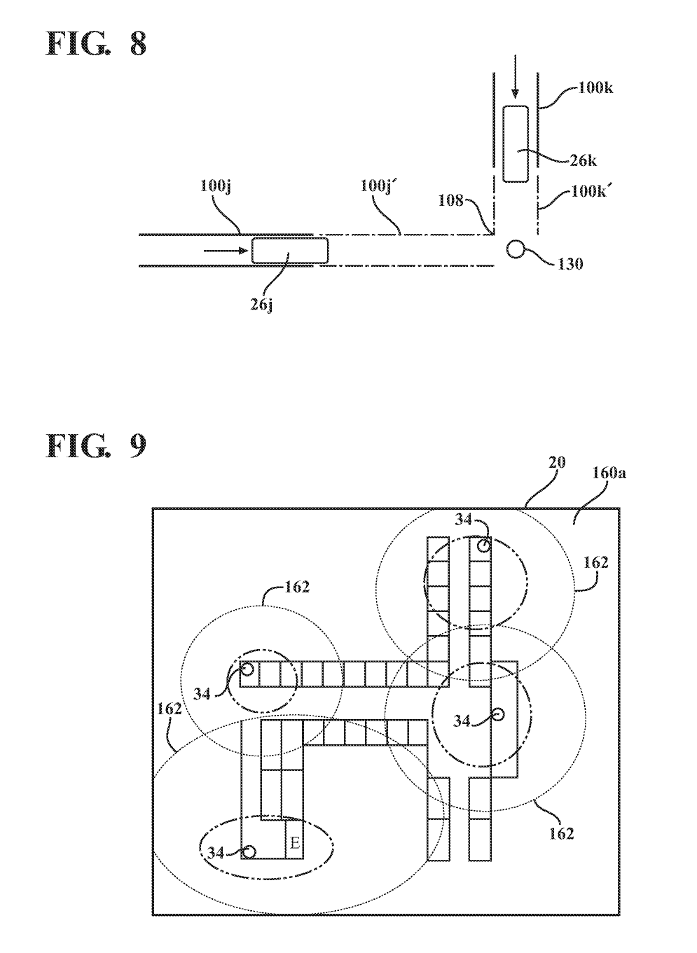

In yet another example, as shown in FIG. 8, the server 30 receives readings from two patient transport apparatuses 26j, 26k that are respectively traversing along different paths 100j, 100k. The readings in this example comprise altitude, velocity, time, distance traveled, and directional heading readings. In this example, the patient transport apparatuses 26j, 26k are detected at the same altitude. However, patient transport apparatus 26j is traveling at a velocity slightly greater than patient transport apparatus 26k, and patient transport apparatus 26j is detected as traveling east while patient transport apparatus 26k is detected as traveling south. Additionally, the calculated traversed distance by patient transport apparatus 26j is greater than that of patient transport apparatus 26k. Using these readings from the sensors 28 (and potentially previous readings), the server 30 is configured to confirm paths 100j, 100k. With paths 100j, 100k confirmed, the server 30 utilizes the probabilistic techniques described herein to extend the confirmed paths 100j, 100k along the respective direction of movement of each patient transport apparatus 26j, 26k to generate predicted paths 100j′, 100k′. The server 30 analyzes the predicted paths 100j′, 100k′ to determine that the paths 100j′, 100k′ will collide at intersection point 130. By determining the intersection point 130, the server 30 is able to resolve the corner 108 of the facility 22 for the virtual map 20. This is the case, even though neither patient transport apparatus 26k, 26j has yet reached the corner 108. Such predictive techniques can be utilized in a variety of ways to generate other features of the virtual map 20.

Additionally, the mapping sub-module 44 may be configured with supplemental algorithms for solving problems relating to loop closing wherein the mapping sub-module 44 attempts to assert that the patient transport apparatus 26 has returned to a previously visited location after updating features of the virtual map 20. Examples of such algorithms for detecting loop closure include, but are not limited to scale-invariant feature transform algorithms and the like.

The virtual map 20, or portions thereof, may be generated in one or more arbitrary (i.e., non-localized) coordinate systems (such as the global coordinate system 92) without localization to any particular fixed location relative to the facility 22. As such, the RPDs 36 may be used to orient (localize) the generated virtual map 20 or portions thereof relative to the real world to improve accuracy of the virtual map 20 in representing the facility 22. In one example, the RPD 36 may be located at the elevator 110 to serve as a reference point for each floor of the facility 22. In other words, the elevator 110 is likely a common fixed (x, y) location relative to multiple floors of the facility 22. When virtual maps 20 of multiple floors are generated, the virtual maps 20 may be orientated using one or more RPDs 36 adjacent the elevator 110 to commonly align all floors of the facility 22. Such localization may be done at the server 30 and/or by the RPD 36 itself.

In addition to localizing the virtual map 20 to the real world, the RPDs 36 may also provide localization of locations or paths of the patient transport apparatuses 26 relative to the facility 22, or the global coordinate system 92. In other words, the location or path of any given patient transport apparatus 26 may be generated in the local coordinate systems 90 of the patient transport apparatus 26, without localization to the global coordinate system 92 or any particular fixed location in the facility 22. For example, when cross talk occurs between two patient transport apparatuses 26, their locations are logged relative to the other in their respective local coordinate systems 90. Although the sensors 28 can provide information about a location or path of the respective patient transport apparatus 26, the server 30 initially may be unaware of how such locations or paths relate to global coordinate system 92 until such locations or paths are transformed to the global coordinate system 92. Such transformation may be performed using, e.g., the RPDs 36, which provide a common registration point between the two coordinate system 90, 92.

As such, the RPDs 36 may be used to localize the generated location or path relative to the real world (e.g., the global coordinate system 92) to improve accuracy of the virtual map 20. In one example, the RPD 36 may be located in an IR wall unit in a high-traffic hallway. Locations or paths of patient transport apparatuses 26 passing through the hallway may be received by the IR wall unit. The server 30, knowing the fixed location of the IR wall unit in the global coordinate system 92, is configured to orient the received locations or paths relative to the IR wall unit.

The RPDs 36 may also be utilized to calibrate any of the sensors 28 of the patient transport apparatuses 26. As described, the sensors 28 are susceptible to drift or noise thereby causing inaccurate measurements that can impact mapping. When the RPD 36 detects presence of the patient transport apparatus 26, the sensor 28 readings can be measured at the RPD 26 and compared, for example, to predetermined calibration data stored for the sensor 28. Deviations from the calibration data can be identified and communication with the controller 80 can be established to update calibration of the sensor 28. This technique may be utilized using software and/or hardware available at each RPD 36. Additionally, the server 30 may be involved with the calibration procedure and may be informed by the patient transport apparatus 26 or the RPD 36 of the existence of any deviations.

Naturally, there may be areas of the facility 22 through which the patient transport apparatuses 26 do not pass. In such situations, dead zones in the virtual map 20 may materialize. The server 30 is configured to recognize such dead zones and determine whether supplemental devices or systems equipped with any of the aforementioned sensors 28 are located or otherwise fixed in the dead zones. Additionally or alternatively, the server 30 may generate a notification for installation of sensors 28 on supplemental devices or systems located in such dead zones. As such, the supplemental devices or systems may provide the requisite readings to populate the dead zones with features of the facility 22 for completion of the virtual map 20.

The virtual map 20, when generated, may be displayed on any suitable electronic digital display of a client computing device. In one example, the client computing device is an analysis computing device 140, which is in communication with the server 30, as shown in FIG. 1. The analysis computing device 140 may be utilized by a designer or overseer of the virtual map 20 and the virtual map 20 may be modified, if appropriate, at the analysis computing device 140 or the server 30. The analysis computing device 140 may be any suitable device, such as a PC, workstation, or mobile device such as a tablet or smart phone, etc.

Alternatively or additionally, the client device may be one or more mobile computing devices 150, such as smart phones, tablets, etc. The mobile computing device 150 may have access to the virtual map 20 through an updatable software application of the mobile computing devices 150. Additionally, application programming interfaces (APIs) may be utilized. An individual likely to visit the facility 22 preferably operates the mobile computing device 150. As such, availability of the virtual map 20 provides benefit to such individuals. Examples of such individuals include, but are not limited to, healthcare personnel, facility maintenance personnel, patients, and the like.

IV. Layering Techniques

When the virtual map 20, or portions thereof, are generated in accordance with the techniques described herein, the server 30 is configured to utilize the layering sub-module 46 to implement advanced techniques for adding supplemental information to the virtual map 20. In one example, the server 30 is configured to generate a layer 160 to be incorporated with the virtual map 20, as shown in FIGS. 9-12.

The layer 160 is a computer-rendered digital image that is positioned over, integrated on, and/or superimposed over the virtual map 20. The layer 160 may be understood as representing a part of the virtual map 20, either as pixels or as modification instructions. More than one layer 160 may be incorporated with the virtual map 20 or stacked on top of each other. The layer 160 may comprise static and/or dynamic (i.e., moving) elements.

Generation of the layer 160 may be facilitated using any suitable technique, such as application programming interfaces (APIs), such as JavaScript APIs, and the like. For example, the layer 160 may comprise visualization data that is stored in memory at the server 30 or remote from the server 30.

One example of the layer 160a is shown in FIG. 9 wherein the layer 160a is provided for displaying real-time signal strengths 162 of access points 34 disposed throughout the facility 22. The signal strengths 162 may vary depending on the configuration of the access point 34 and electromagnetic interferences, such as walls, equipment, etc. The signal strengths 162 may be recorded by the sensors 28 of the patient transport apparatuses 26 and transmitted to the server 30 for analysis by the layering sub-module 46. The signal strengths 162 may be updated in real-time as sensor 28 signals transmit readings in real-time. The virtual map 20 in conjunction with this layer 160a, provides insight into overlap in signal strengths 162 and possible dead zones where access points 34 signals are not reaching. Locations of the access points 34 in the layer 160a may be determined by the server 30 using the probabilistic techniques described herein. Moreover, the signal strengths 162 may be fed back into the probabilistic techniques to further enhance localization of the patient transport apparatuses 26 in the facility 22. The signal strengths 162 may be represented using any suitable visual representation, such as heat maps with colored intensity, etc. In one embodiment, the layer 160a may be overlaid on the virtual map 20 as utilized by the analysis computing device 140 for analysis or diagnostic purposes. Examples of patient transport apparatuses used in monitoring signal strengths are described in United States Patent Application Publication No. 2017/0099198, filed Sep. 29, 2016, and entitled “PERSON SUPPORT APPARATUSES WITH COMMUNICATION CHANNEL MONITORING,” the disclosure of which is hereby incorporated by reference in its entirety.

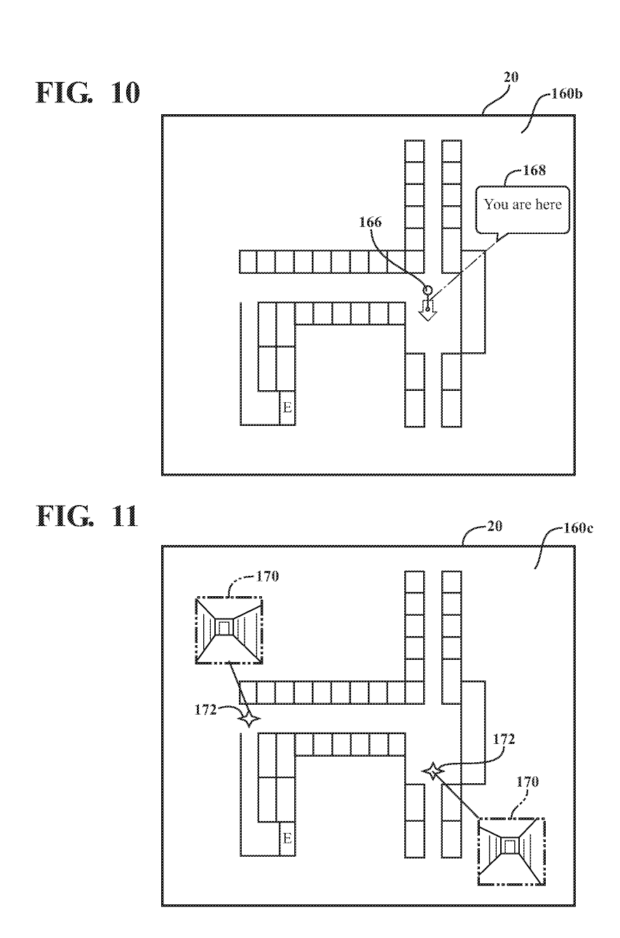

In another example, as shown in FIG. 10, the layer 160b is configured to represent tracked states of the mobile computing device 150 located within the facility 22. For example, such states may be the location and direction of the mobile computing device 150. Here, an individual, such as those described above, moves through the facility 22 with the mobile computing device 150 such that movement of the individual can be inferred from tracked movement of the mobile computing device 150. The virtual map 20 and layer 160b are provided on the display of the mobile computing device 150 for reference by the individual in the facility 22. Movement of the mobile computing device 150 is tracked using any of the localization techniques described herein, including, any one or more of the access points 34, RPDs 36, GPS techniques, sensors 28 of nearby patient transport apparatuses 26, or the like. The layer 160b provides one or more graphical icons 166 to represent the state of the mobile computing device 150 directly on the virtual map 20. For example, the graphical icons 166 may be a pin-drop indicating location of the mobile computing device 150 and a directional arrow indicating orientation of the mobile computing device 150, as shown in FIG. 10. Additionally, the layer 160b may provide textual messages 168 for purposes such as to supplement navigation of the mobile computing device 150, or otherwise. For instance, the textual message 168 may communicate the state of the mobile computing device 150, provide alerts about direction or safety, provide the names of features of the facility, and the like. The virtual map 20 and layer 160b may be zoomed-in, zoomed-out, and rotated by the individual. In some instances, the virtual map 20 and layer 160b may also be configured to enable dynamic navigation through the facility 22 given input from the individual about a desired destination within the facility 22.

In another example, as shown in FIG. 11, the virtual map 20 comprises a layer 160c configured to provide links to camera images 170 of the facility 22. The images 170 are real-world images of the facility 22 taken at selected locations 172 as though an individual were standing at the selected location 172. As such, the layer 160c provides individuals with a reference as to how the facility 22 looks at the selected location 172. The individual may select or click a display of the computing device 140, 150 at the selected locations 172 on the virtual map 20 where the layer 160c indicates images 170 have been captured. The layer 160c is configured to display (as a pop-up, overlay, or in a separate window) images 170 that have been taken for the selected location 172. Ultimately, when enough images 170 have been captured, images 170 of the facility 22 may be displayed for selection of any given point in the facility 22. This type of layer 160c may be implemented with or without the mobile computing device 150 being in the facility 22.

The images 170 may be static or dynamic. In some instances, the images 170 may be panoramic such that the facility 22 is captured at various angles. The images 170 may be acquired using any suitable technique. In one example, the patient transport apparatuses 26 are equipped with cameras for periodically capturing images 170 of the facility 22 as the patient transport apparatuses 26 move throughout the facility for healthcare related purposes. Data from the captured images 170 may be transmitted to the server 30 for analysis by the layering sub-module 46 for generating the layer 160c.

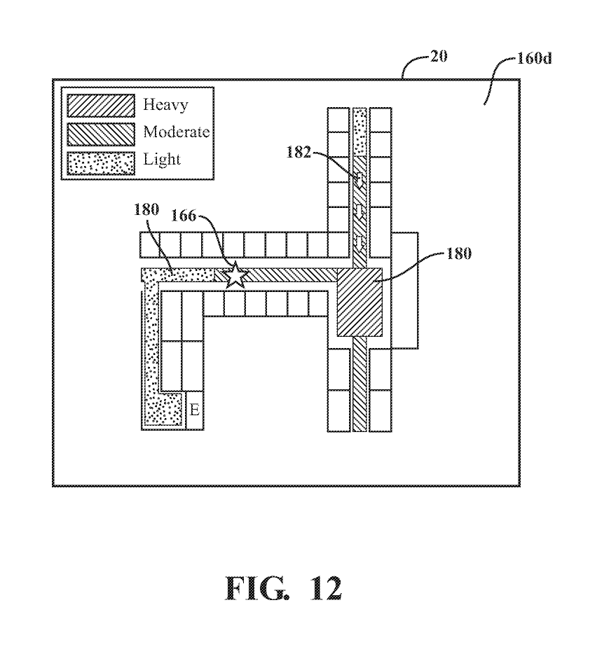

In yet another example, as shown in FIG. 12, the layer 160d is configured to provide real-time traffic within the facility 22. In one embodiment, the traffic specifically relates to traffic from presence of patient transport apparatuses 26. Traffic may also relate to presence of persons, electronic devices, and the like. Traffic may be measured using any of the localization techniques described herein, including, any one or more of the access points 34, RPDs 36, GPS techniques, sensors 28 of patient transport apparatuses 26 (e.g., cross talk), or the like. Data from these sources can be transmitted back to the server 30 for analysis.

In FIG. 12, traffic is indicated using congestion graphics 180 which the layer 160d overlays on the virtual map 20. The congestion graphics 180 may have any suitable configuration for indicating varying levels of traffic or congestion or areas having frequent accidents. For example, the congestion graphics 180 may be colored geometrical features (e.g., red-heavy; orange-moderate; green-light). The congestion graphics 180 may be static or dynamic. Traffic flow directions may be indicated using directional graphics 182, as shown in FIG. 12. Traffic may be represented using any suitable visual representation, such as heat maps with colored intensity, etc. In one embodiment, the layer 160d may be overlaid on the virtual map 20 as utilized by the analysis computing device 140 for analysis or diagnostic purposes. Alternatively, the virtual map 20 and layer 160d are provided on the display of the mobile computing device 150 for reference by the individual in the facility 22. In such instances, the layer 160d may display the state 166 of the mobile computing device 150. In some embodiments, the server 30 may be configured with further modules for implementing traffic algorithms. Such algorithms may be used in conjunction with navigation techniques to suggest alternative routes to a destination given elevated levels of traffic congestion along a conventional route, optimal routes to conserve energy, and the like. In such instances, the virtual map 20 and layer 160d may also be provided on displays on the patient transport apparatuses 26 themselves or on the mobile computing devices 150 to guide personnel moving through the facility 22 with the patient transport apparatuses 26.

Those skilled in the art appreciate that layers other than those described herein may be implemented with the virtual map 20 given the capabilities of the mapping system 24. Furthermore, any of the layers 160a-160d described herein may be utilized in combination such that they are provided in a common layer or different layers.

In other embodiments, once the virtual map 20 is generated it may be utilized for directing patient transport apparatuses 26 configured for autonomous movement. For example, the patient transport apparatus 26, and more specifically, the controller 80 of each patient transport apparatus 26 may have access to the generated virtual map 20 (either locally or remotely) to autonomously control driving, steering, and braking systems of the patient transport apparatus 26 to navigate through the facility 22 based on the virtual map 20. One example of an autonomous driving system that could be utilized is disclosed in U.S. Patent Application Publication No. 2016/0367415, entitled “Patient Support Apparatuses With Navigation And Guidance Systems,” filed on Jun. 17, 2016, hereby incorporated by reference.

It should be appreciated that the terms “include,” “includes,” and “including” have the same meaning as the terms “comprise,” “comprises,” and “comprising.”

Several embodiments have been discussed in the foregoing description. However, the embodiments discussed herein are not intended to be exhaustive or limit the invention to any particular form. The terminology which has been used is intended to be in the nature of words of description rather than of limitation. Many modifications and variations are possible in light of the above teachings and the invention may be practiced otherwise than as specifically described.

1. A mapping system comprising:
a plurality of patient transport apparatuses configured to be located in a facility and being equipped with sensors configured to produce readings as the patient transport apparatuses move in the facility;
a server being configured to receive the readings over a network and to analyze the readings to generate a virtual map of the facility based on analysis of the readings.

2. The mapping system of claim 1 wherein the readings are indicative of paths of the patient transport apparatuses.

3. The mapping system of claim 2 wherein the server is further configured to log locations of the patient transport apparatuses on the paths in response to one or more of:
the sensors recognizing other patient transport apparatuses when the sensors are located proximate to the other patient transport apparatuses; and
a reference point designator being disposed at a fixed location in the facility and being configured to recognize patient transport apparatuses proximate the fixed location.

4. The mapping system of claim 3 wherein the server is further configured to:
align logged locations of the patient transport apparatuses; and
merge paths of the patient transport apparatuses to generate refined paths.

5. The mapping system of claim 4 wherein the server is configured to generate the virtual map by analyzing the paths or refined paths to hypothesize existence of landmarks of the facility.

6. The mapping system of claim 5 wherein the server is configured to test hypothesized existence of landmarks using one or more of a particle filter and a Kalman filter.

7. The mapping system of claim 5 wherein the server is configured to orient the paths, refined paths or the virtual map to the reference point designator.

8. The mapping system of claim 1 further comprising a plurality of access points configured to be disposed throughout the facility and being configured to receive the readings from the patient transport apparatuses and send the readings to the server over the network.

9. The mapping system of claim 1 wherein the server is configured to generate a layer to be incorporated with the virtual map wherein the layer comprises one or more of:
real-time signal strengths of access points disposed throughout the facility;
links to camera images of the facility;
tracked states of a portable computing device located within the facility; and
real-time traffic of the patient transport apparatuses within the facility.

10. The mapping system of claim 1 wherein the sensors comprise one or more of:
altimeters configured to produce readings indicative of altitudes of the patient transport apparatuses;
velocity sensors configured to produce readings indicative of velocities of the patient transport apparatuses;
accelerometers configured to produce readings indicative of accelerations of the patient transport apparatuses or readings used to derive velocities, positions or inclinations of the patient transport apparatuses;
gyroscopes configured to produce readings indicative of direction of the patient transport apparatuses;
magnetometers configured to produce readings indicative of direction of the patient transport apparatuses;
tachometers configured to produce readings indicative of rotational speeds of wheels of the patient transport apparatuses;
infrared sensors configured to produce readings for recognition of other patient transport apparatuses; and
GPS sensors to produce readings indicative of positions of the patient transport apparatuses.

11. A method for generating a virtual map of a facility using a plurality of patient transport apparatuses being located in a facility and being equipped with sensors, and a server coupled to the sensors over a network, the method comprising:
producing readings with the sensors as the patient transport apparatuses move in the facility;
receiving the readings over the network with the server; and
analyzing the readings with the server to generate the virtual map of the facility.

12. The method of claim 11 wherein producing readings is further defined as producing readings indicative of paths of the patient transport apparatuses.

13. The method of claim 12 further comprising logging, with the sensors, locations of the patient transport apparatuses on the paths in response to one or more of:
recognizing other patient transport apparatuses when the sensors are located proximate to the other patient transport apparatuses; and
recognizing, with a reference point designator being disposed at a fixed location in the facility, patient transport apparatuses proximate the fixed location.

14. The method of claim 13 further comprising the server:
aligning logged locations of the patient transport apparatuses; and
merging paths of the patient transport apparatuses to generate refined paths.

15. The method of claim 14 further comprising the server generating the virtual map by analyzing the paths or refined paths to hypothesize existence of landmarks of the facility.

16. The method of claim 15 further comprising the server testing hypothesized existence of landmarks using one or more of a particle filter and a Kalman filter.

17. The method of claim 15 further comprising orienting, with the server, the paths, refined paths or the virtual map to the reference point designator.

18. The method of claim 11 further comprising receiving the readings from the patient transport apparatuses with a plurality of access points disposed throughout the facility and sending, with the access points, the readings over the network to the server.

19. The method of claim 11 further comprising the server generating a layer to be incorporated with the virtual map wherein the layer comprises one or more of:
real-time signal strengths of access points disposed throughout the facility;
links to camera images of the facility;
tracked states of a portable computing device located within the facility; and
real-time traffic of the patient transport apparatuses within the facility.

20. A server for generating a virtual map of a facility, the server being coupled over a network to sensors equipped on patient transport apparatuses being located in the facility, the sensors producing readings as the patient transport apparatuses move in the facility, the server being configured to:
receive the readings over the network; and
analyze the readings to generate the virtual map of the facility.
